(19) United States
(12) Patent Application Publication
(10) Pub. No.: US 2010/0302826 A1
(43) Pub. Date: Dec. 2, 2010

(54) CAM CELL CIRCUIT OF NONVOLATILE MEMORY DEVICE AND METHOD OF DRIVING THE SAME

(76) Inventor: Myung Su KIM, Gyeonggi-do (KR)

Correspondence Address: IP & T GROUP LLP, 7700 Little River Turnpike, Suite 207, Annandale, VA, 22003, US

(21) Appl. No.: 12/650,689

(22) Filed: Dec. 31, 2009

(30) Foreign Application Priority Data
May 29, 2009 (KR) 10-2009-0047813

(51) Int. Cl. G11C 15/00; G11C 7/10

(52) U.S. Cl. 365/49.1; 365/189.05

(57) ABSTRACT

A Code Address Memory (CAM) cell circuit of a nonvolatile memory device includes a CAM cell unit configured to store data, a control circuit unit configured to read data stored in the CAM cell unit and to output data read as read data, and register units each configured to comprise a number of registers for storing the read data. Each of the registers is reset such that first data are latched when a reset operation is performed, and is configured to maintain the first data or newly latch second data in response to the read data.

### CROSS-REFERENCE TO RELATED APPLICATION

Priority to Korean patent application number 10-2009-0047813 filed on May 29, 2009, the entire disclosure of which is incorporated by reference herein, is claimed.

### BACKGROUND

Exemplary embodiments relate to a Code Address Memory (hereinafter referred to as ‘CAM’) cell circuit of a nonvolatile memory device and a method of driving the same and, more particularly, to a CAM cell circuit of a nonvolatile memory device and a method of driving the same, which are capable of detecting a CAM cell without a program operation on the CAM cell and setting desired data in a register.

A nonvolatile memory cell which can be electrically programmed and erased has a basic structure, including a stack gate of a floating gate and a control gate, a source, and a drain. This nonvolatile memory cell is configured to perform a program, erase, or read operation by supplying a specific voltage to a control gate, the source, the drain, and a well.

Nonvolatile memory devices, such as a flash memory device may include memory cell arrays in which a number of memory cells are coupled together by word lines and bit lines. Such a flash memory device includes a main cell array, a redundancy cell array, and a CAM cell array. The main cell array includes memory cells for performing program operations, erase operations, etc. The redundancy cell array includes memory cells for repairing fail cells included in the main cell array. The CAM cell array includes memory cells for storing information about normal cells or fail cells.

A known nonvolatile memory device may include a CAM cell detection circuit for detecting information about a CAM cell. The CAM cell detection circuit may be configured to detect the information of the CAM cell and to store it in a register.

Further, the register may be configured to store information about the operation of the device. This information may be updated after the information of the CAM cell is stored. Accordingly, desired data can be stored in the register only when the CAM cell is programmed after a chip is fabricated.

### BRIEF SUMMARY

Exemplary embodiments relate to a CAM cell circuit of a nonvolatile memory device and a method of driving the same, which are capable of reducing the number of CAM cells to be programmed. In the exemplary embodiments, a CAM cell circuit is operated in such a manner that, when a reset operation is performed on a register corresponding to data stored in a CAM cell, first data are latched. Then when the first data latched in the reset operation are maintained or changed, only the corresponding CAM cell is programmed and second data are latched in the corresponding register.

A CAM cell circuit of a nonvolatile memory device according to an aspect of the present disclosure includes a CAM cell unit configured to comprise a number of CAM cells, a control circuit unit configured to read data stored in the CAM cells and to output the data read as CAM cell data, and a number of registers configured to store the CAM cell data. The registers are reset to store first data when a reset operation is performed.

The CAM cell unit is configured to program only a CAM cell corresponding to a specific one of the registers in order to change the first data into second data.

Each of the registers includes a latch configured to store data, and a data input unit configured to input the first data to the latch in response to a reset signal when a reset operation is performed and to input the second data to the latch in response to the CAM cell data.

The latch includes first and second inverters coupled in parallel between first and second nodes in a reverse direction to each other.

The data input unit includes a first transistor configured to supply a ground power source to the first node in response to the reset signal, and a second transistor configured to supply the ground power source to the second node in response to the CAM cell data.

Alternatively, the data input unit includes a first transistor configured to supply a ground power source to the second node in response to the reset signal, and a second transistor configured to supply the ground power source to the first node in response to the CAM cell data.

A method of driving a CAM cell circuit of a nonvolatile memory device according to another aspect of the present disclosure includes resetting a number of registers and storing first data in the number of the registers, programming a CAM cell corresponding to a specific register in which second data will be stored, from among the registers, reading CAM cell data programmed into the CAM cell, and storing the second data in the specific register using the CAM cell data.

### BRIEF DESCRIPTION OF THE DRAWINGS

FIG. 1 is a block diagram showing the construction of a CAM cell circuit of a nonvolatile memory device according to an embodiment of this disclosure;

FIG. 2A is a circuit diagram of a register according to a first embodiment of this disclosure; and

FIG. 2B is a circuit diagram of a register according to a second embodiment of this disclosure.

### DESCRIPTION OF EMBODIMENTS

Hereinafter, some embodiments of the present disclosure will be described in detail with reference to the accompanying drawings. The figures are provided to allow those having ordinary skill in the art to understand the scope of the embodiments of the disclosure.

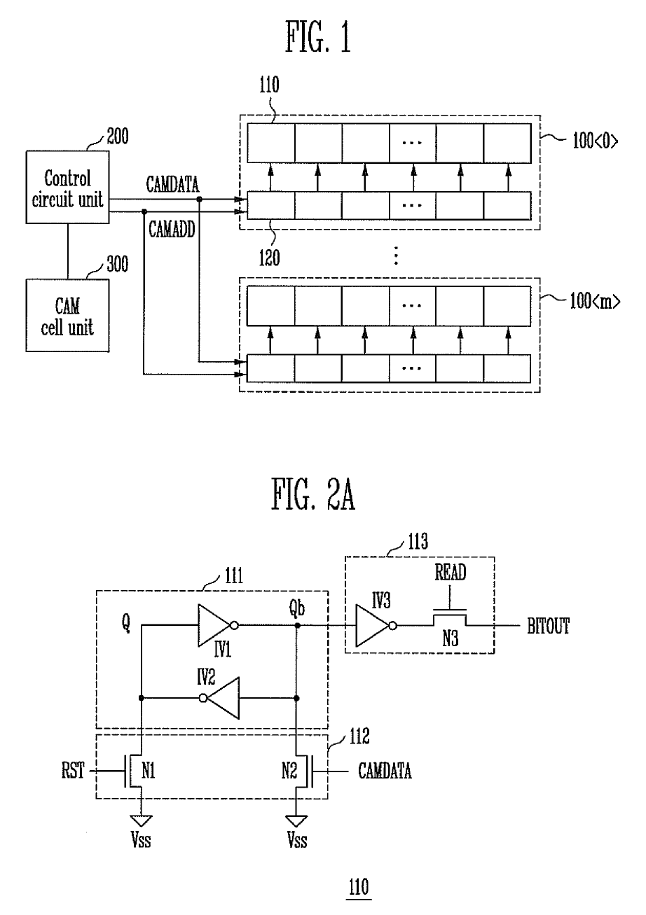

FIG. 1 shows the construction of a CAM cell circuit of a nonvolatile memory device according to an embodiment of this disclosure.

Referring to FIG. 1, the CAM cell circuit of the nonvolatile memory device includes a number of register units 100<0> to 100<m>, a control circuit unit 200, and a CAM cell unit 300.

The CAM cell unit 300 includes a number of CAM cells into which data can be programmed.

The control circuit unit 200 is configured to output an address signal CAMADD and CAM cell data CAMDATA, read from the CAM cell unit 300, to the register units 100<0> to 100<m>.

Each of the register units 100<0> to 100<m> includes a number of registers 110 and a number of address comparators 120 respectively corresponding to the registers 110. The address comparators 120 are configured to send the CAM cell data CAMDATA to a designated register in response to the address signal CAMADD.

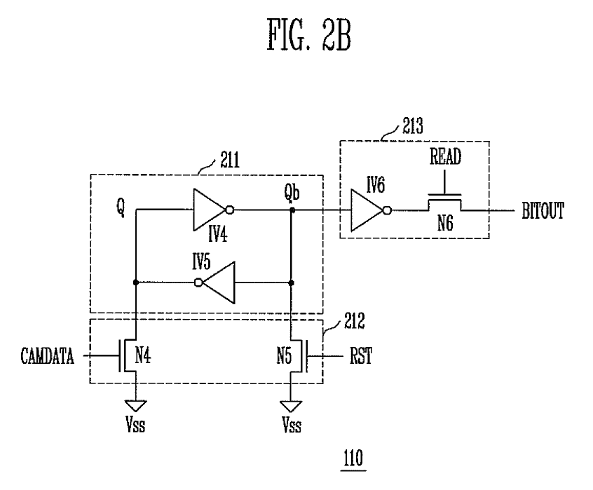

FIG. 2A is a circuit diagram of the register according to a first embodiment of this disclosure.

Referring to FIG. 2A, the register 110 includes a latch 111, a data input unit 112, and a data output unit 113.

The latch 111 includes inverters IV1 and IV2 coupled in parallel between a first node Q and a second node Qb in a reverse direction to each other. In other words, the output of the first inverter IV1 is coupled to the input of the second inverter IV2, while the output of the second inverter IV2 is coupled to the input of the first inverter IV1.

The data input unit 112 includes NMOS transistors N1 and N2. The NMOS transistor N1 is coupled between a ground power source Vss and the first node Q of the latch 111. Furthermore, the NMOS transistor N1 is configured to supply the first node Q with the ground power source Vss in response to a reset signal RST. The NMOS transistor N2 is coupled between the ground power source Vss and the second node Qb of the latch 111. Furthermore, the NMOS transistor N2 is configured to supply the second node Qb with the ground power source Vss in response to the CAM cell data CAMDATA.

The data output unit 113 includes an inverter IV3 and an NMOS transistor N3. The inverter IV3 and the NMOS transistor N3 are coupled in series between the second node Qb and an output node BITOUT. The NMOS transistor N3 is configured to output an output signal of the inverter IV3 as a register output signal in response to a read signal READ.

FIG. 2B is a circuit diagram of a register according to a second embodiment of this disclosure.

Referring to FIG. 2B, the register 110 includes a latch 211, a data input unit 212, and a data output unit 213.

The latch 211 includes inverters IV4 and IV5 coupled in parallel between a first node Q and a second node Qb in a reverse direction to each other. In other words, the output of the fourth inverter IV4 is coupled to the input of the fifth inverter IV5, while the output of the fifth inverter IV5 is coupled to the input of the fourth inverter IV4.

The data input unit 212 includes NMOS transistors N4 and N5. The NMOS transistor N4 is coupled between a ground power source Vss and the first node Q of the latch 211. Furthermore, the NMOS transistor N4 is configured to supply the first node Q with the ground power source Vss in response to the CAM cell data CAMDATA. The NMOS transistor N5 is coupled between the ground power source Vss and the second node Qb of the latch 211. Furthermore, the NMOS transistor N5 is configured to supply the second node Qb with the ground power source Vss in response to a reset signal RST.

The data output unit 213 includes an inverter IV6 and an NMOS transistor N6. The inverter IV6 and the NMOS transistor N3 are coupled in series between the second node Qb and an output node BITOUT. The NMOS transistor N6 is configured to output an output signal of the inverter IV6 as a register output signal in response to a read signal READ.

A method of driving the CAM cell circuit of the nonvolatile memory device according to an embodiment of the present disclosure is described below with reference to FIGS. 1, 2A, and 2B.

First, in the initial operation, all the CAM cells of the CAM cell unit 300 have a data state (“1”) of an erase state, because a program operation has not been performed.

A reset operation performed on the register 110 of FIG. 2A according to the first embodiment of the present invention is described below. During the reset operation, the reset signal RST is activated and supplied to the NMOS transistor N1. In response thereto, the NMOS transistor N1 is turned on, and so the ground power source Vss is supplied to the first node Q of the latch 111. Thus, the latch 111 is reset.

Next, the control circuit unit 200 reads the CAM cell data CAMDATA (“1”) (i.e., an erase state) of the CAM cell unit 300, and sends the read CAM cell data CAMDATA (“1”) (i.e., a high level) and the address signal CAMADD to a number of the register units 100<0> to 100<m>.

The NMOS transistor N2 of the register 110 is turned on in response to the CAM cell data CAMDATA of a high level, and so the ground power source Vss is supplied to the second node Qb of the latch 111. Thus, the CAM cell data CAMDATA of an erase state is stored in the latch 111.

A reset operation performed on the register 110 of FIG. 2B according to the second embodiment is described below.

During the reset operation, the reset signal RST is activated and supplied to the NMOS transistor N5. In response thereto, the NMOS transistor N5 is turned on, and the ground power source Vss is supplied to the second node Qb of the latch 211. Thus, the latch 211 is reset.

Next, the control circuit unit 200 reads CAM cell data “1” (i.e., an erase state) of the CAM cell unit 300, and sends the read CAM cell data CAMDATA (“1”) of an erase state and the address signal CAMADD to a number of the register units 100<0> to 100<m>.

The NMOS transistor N4 of the register 110 is turned on in response to the CAM cell data CAMDATA of a high level, and so the ground power source Vss is supplied to the first node Q of the latch 211. Accordingly, the CAM cell data CAMDATA of an erase state is stored in the latch 211.

As described above, the initial value of a register can be set in different manners according to the first embodiment and the second embodiment.

After setting the initial values of registers as described above, only a CAM cell corresponding to a register (for example, the register 110) whose initial value will be changed is programmed to have a data state “0”. Accordingly, the number of CAM cells to be programmed can be reduced because, in the case in which a program operation is performed on CAM cells, all the CAM cells are not programmed. On the contrary, only a CAM cell corresponding to a register whose initial value will be changed is programmed, and data are stored in the corresponding CAM cell.

According to the exemplary embodiments of the present disclosure, when a reset operation is performed on a register corresponding to data stored in a CAM cell, first data are latched. Then when the first data latched in the reset operation are maintained or changed, only the corresponding CAM cell is programmed, and second data are latched in the corresponding register. Accordingly, the number of CAM cells to be programmed can be reduced.

What is claimed is:

1. A Code Address Memory (CAM) cell circuit of a nonvolatile memory device, the circuit comprising:
a CAM cell unit configured to store data;
a control circuit unit configured to read data stored in the CAM cell unit and to output data read as read data; and
register units each configured to comprise a number of registers for storing the read data,
wherein each of the registers is reset such that first data are latched when a reset operation is performed, and is configured to maintain the first data or newly latch second data in response to the read data.

2. The CAM cell circuit of claim 1, wherein the CAM cell unit is configured to program only a CAM cell corresponding to a specific one of the registers in order to change the first data into the second data and store the second data in the specific one of the registers.

3. The CAM cell circuit of claim 1, wherein each of the registers comprises:
a latch configured to store the first data or the second data; and
a data input unit configured to input the first data to the latch in response to a reset signal in the reset operation and to maintain the first data latched in the latch or newly input the second data to the latch in response to the read data.

4. The CAM cell circuit of claim 3, wherein the latch comprises first and second inverters coupled in parallel between first and second nodes in a reverse direction to each other.

5. The CAM cell circuit of claim 4, wherein the data input unit comprises:
a first transistor configured to supply a ground power source to the first node in response to the reset signal; and
a second transistor configured to supply the ground power source to the second node in response to data stored in a CAM cell.

6. The CAM cell circuit of claim 4, wherein the data input unit comprises:
a first transistor configured to supply a ground power source to the second node in response to the reset signal; and
a second transistor configured to supply the ground power source to the first node in response to data stored in a CAM cell.

7. A CAM cell circuit of a nonvolatile memory device, the circuit comprising:
a CAM cell unit configured to comprise a number of CAM cells;
a control circuit unit configured to read data stored in the CAM cells and to output the data read as CAM cell data; and
a number of registers configured to store the CAM cell data,
wherein the registers are reset to store first data when a reset operation is performed.

8. The CAM cell circuit of claim 7, wherein the CAM cell unit is configured to program only a CAM cell corresponding to a specific one of the registers in order to change the first data into second data.

9. The CAM cell circuit of claim 7, wherein each of the registers comprises:
a latch configured to store data; and
a data input unit configured to input the first data to the latch in response to a reset signal when a reset operation is performed and to input the second data to the latch in response to the CAM cell data.

10. The CAM cell circuit of claim 9, wherein the latch comprises first and second inverters coupled in parallel between first and second nodes in a reverse direction to each other.

11. The CAM cell circuit of claim 10, wherein the data input unit comprises:
a first transistor configured to supply a ground power source to the first node in response to the reset signal; and
a second transistor configured to supply the ground power source to the second node in response to the CAM cell data.

12. A method of driving a CAM cell circuit of a nonvolatile memory device, the method comprising:
resetting a number of registers and storing first data in the number of the registers;
programming a CAM cell corresponding to a specific register in which second data will be stored, from among the registers;
reading CAM cell data programmed into the CAM cell; and
storing the second data in the specific register using the CAM cell data.
